(19) United States
(12) Patent Application Publication
(10) Pub. No.: US 2026/0258298 A1
(43) Pub. Date: Sep. 3, 2026

(54) LIGHT EMISSION FROM ELECTRICALLY CONTROLLED HYPERBOLIC MEDIA

(71) Applicant: The Regents of the University of California, Oakland, CA (US)

(72) Inventors: Juan Sebastian Gomez-Diaz, Davis, CA (US); Joshua L. Hihath, Davis, CA (US); Luqi Wang, Davis, CA (US)

(73) Assignee: The Regents of the University of California, Oakland, CA (US)

(21) Appl. No.: 19/163,593

(22) PCT Filed: Mar. 8, 2024
(86) PCT No.: PCT/US2024/019161

§ 371 Date: Sep. 9, 2025

Related U.S. Application Data
(60) Provisional application No. 63/489,586, filed on Mar. 10, 2023.

(51) Int. Cl. C09K 11/65; H10H 20/812

(52) U.S. Cl. CPC C09K 11/65; H10H 20/812

(57) ABSTRACT

Apparatus, systems, and methods are provided for generating Cherenkov radiation (CR) at terahertz, infrared, and/or other frequency ranges without an exotic power source such as a nuclear reactor. A hyperbolic meta-material structure may take the form of a stack comprising multiple hyperbolic layers (e.g., graphene sandwiched within hexagonal boron nitride (hBN)) interleaved with dielectric and topped with one or more outcoupling layers for emitting photonic CR based on coupling between drifting electrons within the hyperbolic layers and compatible photonic modes. A hyperbolic metasurface structure is substantially planar in form, comprises multiple hyperbolic strips (e.g., and emits CR in the form of surface plasmon polaritons (SPPs).

### RELATED APPLICATION(S)

This application claims the benefit of U.S. Provisional Patent Application No. 63/489,586, filed 10 Mar. 2023 (docket number UC 22-543-2PSP), the contents of which are incorporated by reference herein.

### GOVERNMENT LICENSE RIGHTS

This invention was made with U.S. Government support under Grant No. 1749177, awarded by the National Science Foundation. The U.S. Government has certain rights in the invention.

### BACKGROUND

This disclosure relates to the field of electrical engineering. More particularly, apparatus and methods are provided for solid-state generation of light using Cherenkov radiation and hyperbolic media.

Instruments and tools for generating light continually evolve. Since the invention of the incandescent light bulb, which emitted light generated by thermal radiation, mankind has developed thermionic emission (e.g., vacuum tubes), stimulated emission (e.g., lasers, spasers), and electroluminescence (e.g., light-emitting diodes or LEDs), and incorporated these developments into everyday life.

However, adoption of Cherenkov (or Cerenkov) radiation (CR) has been limited to specialized applications such as medical imaging and particle detection, at least in part because CR requires highly energetic electrons, which have primarily been produced by a sophisticated source such as a nuclear reactor or radionuclide generator. In particular, generation of CR has required the passage of a charged particle through a medium at a speed that is faster than the speed of light through the same medium, which has been limited to environments that include a nuclear reactor, particle accelerator or radionuclide generator.

### SUMMARY

In some embodiments, apparatus and methods are provided for generating light in the TeraHertz (THz), InfraRed (IR) and visible regions of the electromagnetic spectrum, and/or other high-energy regions, by employing hyperbolic material and harnessing Cherenkov radiation (CR). In these embodiments, low-energy electrons are accelerated by an electric field and emit light even while traveling slower than the speed of light through the material.

In some embodiments, couplings are manipulated between drifting electrons and hyperbolic photonic modes in nanostructures made from two-dimensional (2D) materials and/or interleaved layers of plasmonic and dielectric materials. As a result, CR can be generated and controlled in the form of emitted photons and/or surface plasmon polaritons (SPPs) without electron beams or exotic energy sources.

In some embodiments, drift-biased graphene facilitates the acceleration of electrons while a graphene-based hyperbolic material tailors photonic states. The graphene may be nanopatterned with shapes to create the hyperbolic modes and/or may include quantum dots. Application of an appropriate bias voltage enables CR at frequencies across the electromagnetic spectrum (e.g., in the TeraHertz (THz), infrared, and/or visible ranges). In other embodiments, instead of graphene, a different 2D material or even an ultrathin metallic layer (e.g., 5-10 nm thick) may be employed.

In some implementations, an apparatus for yielding CR is constructed as a stack comprising multiple sandwiches of graphene and a compatible material such as hexagonal Boron Nitride (hBN), separated by dielectric, and topped with a suitable matching layer. When a bias voltage is applied to the apparatus, photons are emitted into free space. In other implementations, an apparatus features multiple ribbons of graphene laid down on hBN or some other compatible material. When subjected to a bias voltage, waves of surface plasmon polaritons (SPPs) are emitted.

### DESCRIPTION OF THE FIGURES

FIG. 1A illustrates a hyperbolic structure for emitting Cherenkov radiation in the form of photons, according to some embodiments.

FIG. 1B depicts a complete hyperbolic nanostructure based on the stack shown in FIG. 1A, according to some embodiments.

FIG. 1C depicts a radiation pattern of the hyperbolic structure of FIG. 1B, according to some embodiments.

FIG. 2A illustrates a hyperbolic structure for emitting Cherenkov radiation in the form of surface plasmon polaritons, according to some embodiments.

FIG. 2B depicts a radiation pattern of the hyperbolic material of FIG. 2A, according to some embodiments.

FIGS. 3A-C illustrate an electron/photon coupling space according to some embodiments.

FIGS. 4A-C depict construction of a hyperbolic metamaterial nanostructure for emitting Cherenkov radiation in the form of photons, according to some embodiments.

FIG. 5 depicts construction of a hyperbolic metamaterial nanostructure for emitting Cherenkov radiation in the form of surface plasmon polaritons, according to some embodiments.

FIG. 6 is a flowchart demonstrating a method of producing light in the form of Cherenkov radiation using hyperbolic nanostructures, according to some embodiments.

### DETAILED DESCRIPTION

The following description is presented to enable any person skilled in the art to make and use the disclosed embodiments, and is provided in the context of one or more practical applications and their requirements. Various modifications to the disclosed embodiments will be readily apparent to those skilled in the art, and the general principles defined herein may be applied to other embodiments and applications without departing from the scope of those that are disclosed. Thus, the present invention or inventions are not intended to be limited to the embodiments shown, but rather are to be accorded the widest scope consistent with the disclosure.

In some embodiments, Cherenkov radiation (CR) is harnessed at long wavelengths through manipulation of the coupling between drifting electrons and hyperbolic photonic modes within structures (e.g., nanostructures) composed of 2D (two-dimensional) materials. Enforcing couplings between electrons flowing through the materials and photonic modes that the material supports enables generation of light at wavelengths not previously feasible in an everyday environment. In particular, CR in the form of emitted photons and/or surface plasmon polaritons (SPPs) can be generated within the terahertz (THz) and infrared (IR) bands of electromagnetic radiation without electron beams or other exotic energy sources. By controlling the properties of the structures (e.g., size, shape, arrangement, periodicity) and/or an applied voltage, radiation can be emitted at desired wavelengths.

In different embodiments, the intensity, bandwidth, and/or operational frequencies of the electron/photon coupling are altered, as well as, or instead of, gate voltages or biases applied to the nanostructures. Tuning of these properties, and/or others, enables development of efficient, tunable, and broadband electromagnetic emitters that operate at room temperature and in a portable or semi-portable format. Apparatus and methods described herein may therefore provide measurable improvements in resolution, timing, speed, and/or other qualities within the fields of communications, quantum photonics, nano photonics, sensing, healthcare imaging, etc.

Hyperbolic metamaterials (HMTM) exhibit a metallic or dielectric response to an applied voltage, depending on the polarization of the electric field, and support confined photonic modes that enable generation of Cherenkov radiation. Meanwhile, drift-based graphene enables generation of surface plasmon polaritons (SPPs) through exploitation of the interaction between highly mobile electrons within the material and its naturally plasmonic nature. Some embodiments described herein leverage the nature and properties of HMTMs and graphene plasmonics to yield hyperbolic nanostructures capable of enforcing and controlling electron/photon couplings, and thereby generate photons and/or SPPs at desired frequencies or with desired spectra. A hyperbolic nanostructure provided herein may have one or more dimensions on the order of a few hundred nanometers, such that a wave transiting the nanostructure samples its full expanse.

In place of graphene, which allows injection of hot carriers with a suitable voltage (e.g., 1-5 volts, which may be sinusoidal, square wave, or pulsed) and facilitates tailoring of hyperbolic photonic/plasmonic modes (e.g., via nanolithography), some other highly doped semiconductor or 2D material that is highly conductive and plasmonic may be employed. In the latter implementations the 2D material may comprise transition metal dichalcogenides (TMDs); nano-size monolayer molybdenum disulfide (MoS₂); one or more (e.g., an array of) carbon nanotubes; black phosphorous; and/or a 2D electron gas (as with highly-doped semiconductors). The selected material(s) may be layered and/or arranged in a periodic repeating pattern, as described herein and/or in other manners, to form a given structure or nanostructure.

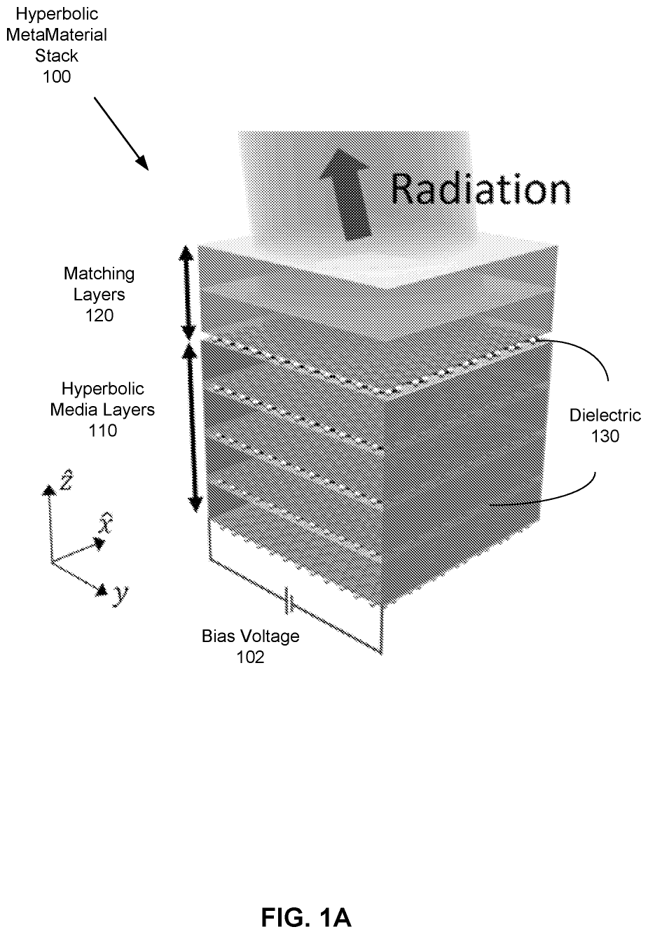

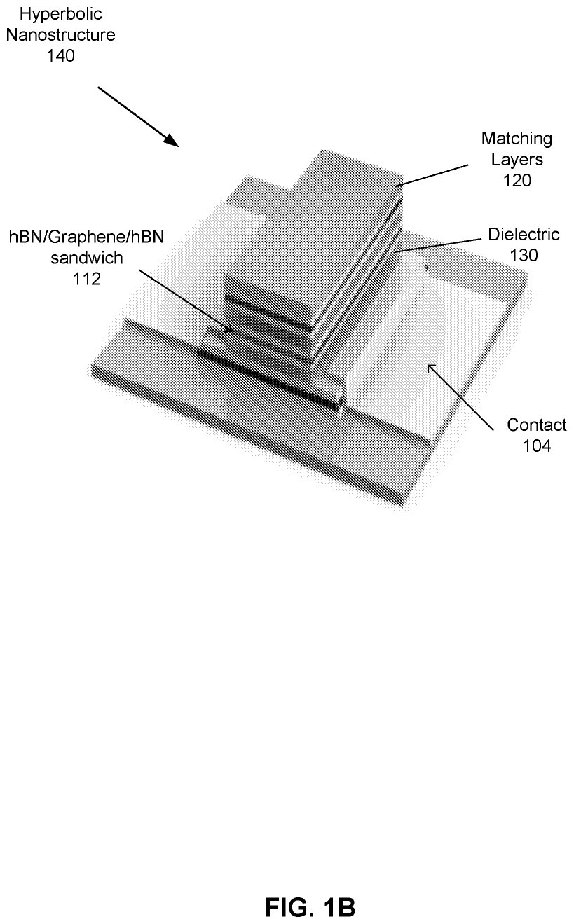

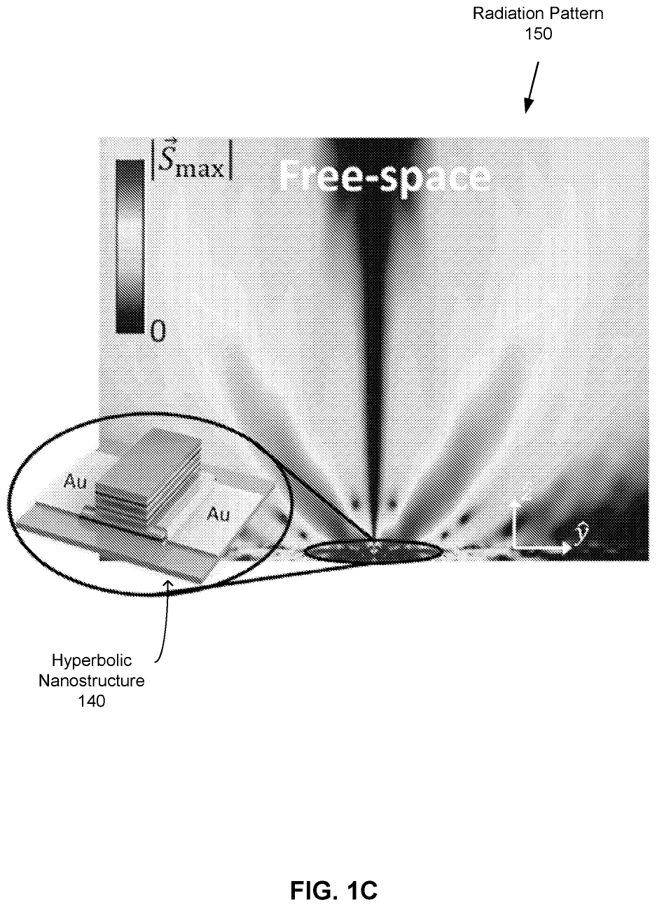

FIG. 1A illustrates a hyperbolic metamaterial stack for emitting Cherenkov radiation in the form of photons, according to some embodiments. In these embodiments, stack 100 is approximately 0.5 μm tall and comprises multiple layers 110 of a selected hyperbolic material (e.g., graphene) separated by layers of dielectric 130 (e.g., silicon dioxide). The dielectric layers may be on the order of 100 nm thick, while the hyperbolic media layers 110 may be hundreds of nanometers thick. Atop the stack structure are one or more matching layers 120 (e.g., to provide optical matching) that outcouple hyperbolic waves to free space and/or patterned graphene, quantum dots, and/or nanoparticles. By varying the thicknesses of the layers of metamaterial, the output of the stack can be altered, in terms of the width of the broadband output frequency range, the starting and/or ending frequencies of the output, the efficiency of the structure, and/or other characteristics.

Bias voltage 102, in the illustrated embodiments, is a direct current (DC) voltage that drives electrons to transit the hyperbolic material layers, during which they couple with photonic modes of the material to cause emission of photons. Contacts made of gold or another exceptional conductor may be used for carrier injection.

In some embodiments, and as further described below, within hyperbolic metamaterial stack 100 graphene layers may be encapsulated in hexagonal boron nitride (hBN) or another substance that enhances carrier mobility. Thus, stack 100 of FIG. 1A may, in some implementations, comprise multiple alternating layers or sandwiches of hBN, graphene, hBN, and dielectric that create a structure that melds drift-biased graphene and hyperbolic photonic modes.

FIG. 1B depicts a complete hyperbolic metamaterial nanostructure based on the stack shown in FIG. 1A, according to some embodiments. In these embodiments, and as described above with reference to FIG. 1A, hyperbolic nanostructure 140 comprises multiple hyperbolic layers in the form of hBN/graphene/hBN sandwiches 112, which are separated by layers of dielectric 130. The structure is topped with matching layers 120, while contacts 104 supply the bias voltage for triggering electron drift.

FIG. 1C illustrates a simulated radiation pattern of the hyperbolic nanostructure of FIG. 1B, according to some embodiments. In particular, radiation pattern 150 depicts a plane-wave CR emission pattern originating from hyperbolic nanostructure 140.

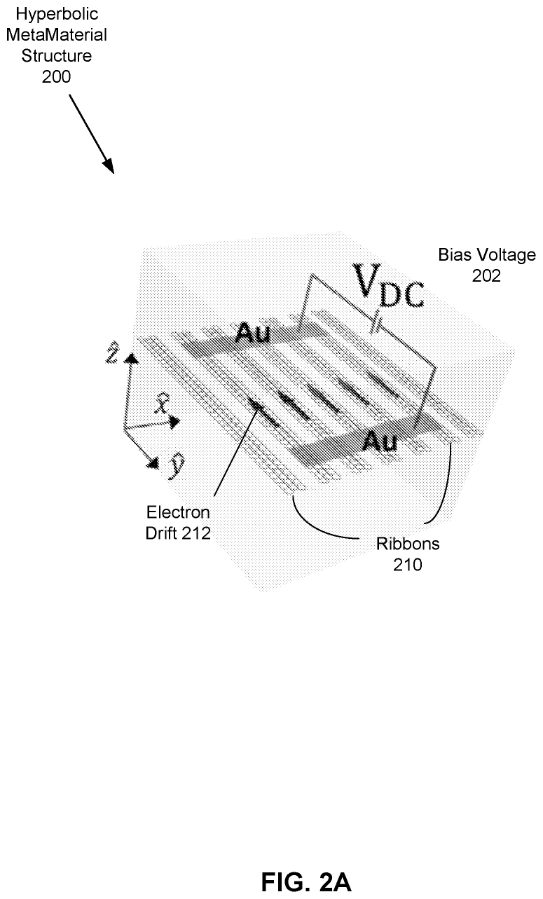

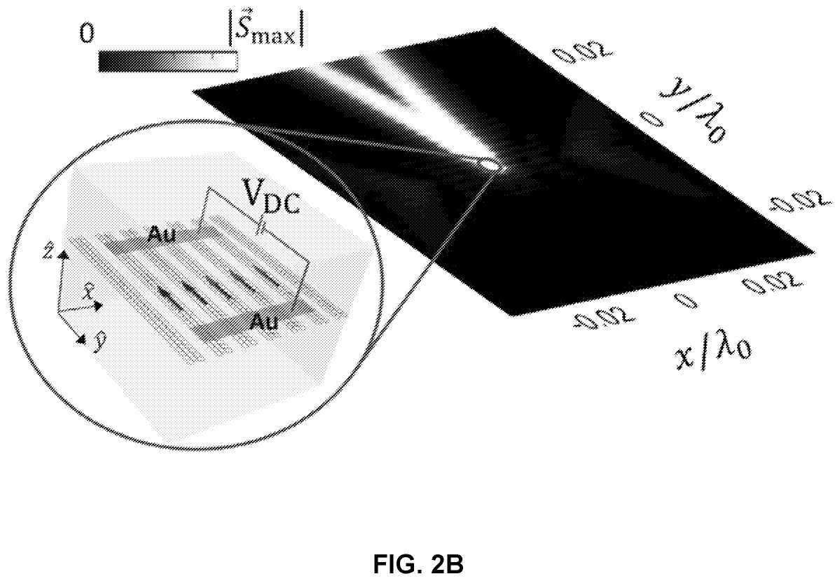

FIG. 2A illustrates a hyperbolic structure for emitting Cherenkov radiation in the form of surface plasmon polaritons, according to some embodiments. In these embodiments, hyperbolic metamaterial structure (or surface) 200 is planar in form and comprises multiple ribbons (or strips) 210 to which bias voltage 202 is applied (e.g., via gold contacts) to induce electron drift 212. In some implementations, each ribbon 210 comprises a layer of graphene deposited upon hBN, wherein the width of each ribbon is approximately 50 nm and repeats approximately every 100 nm. Between each ribbon is a gap and/or dielectric separator approximately 50 nm wide. As with stack 100 of FIG. 1A, the composition and geometry (e.g., dimensions, periodicity) of structure 200 facilitates control of the resulting CR that, in these embodiments, comprises SPPs instead of photons. For example, in other implementations, each ribbon is approximately 150-200 nm wide, and is separated from adjacent ribbons by gaps of 150-200 nm.

Again, by varying the widths, lengths, and/or periodicities of the metamaterial ribbons, characteristics of the output radiation can be altered. For example, when the ribbons are approximately 50 nm wide and separated by similar distances, the output CR may range from approximately 4 to 20 THz. When the dimensions are approximately 200 nm instead of 50 nm, the output may range from approximately 7 to 30 THz. Depending on the desired application (e.g., sensing, spectroscopy), a metamaterial nanostructure provided herein may be configured accordingly.

FIG. 2B depicts a radiation pattern of the hyperbolic metasurface of FIG. 2A, according to some embodiments. In these embodiments, application of bias voltage V_{DC} causes planar emission of SPPs along the y-axis of the x-y plane comprising the hyperbolic metasurface. The plane is marked with numerical simulations reflecting the Cherenkov radiation (e.g., with a power density of 10 THz).

Hyperbolic structures such as those depicted in FIGS. 1A and 2A, and/or others described herein, facilitate electron/photon couplings by phase-matching electrons flowing through a hyperbolic material (e.g., graphene) with confined hyperbolic modes, thereby inducing a high rate of photon (or SPP) emission in the form of Cherenkov radiation. More particularly, the materials, which may be essentially two-dimensional, exhibit a high density of confined photonic states over a broad frequency range. The materials may be stacked as shown in FIG. 1A, or patterned at the nanoscale as shown in FIG. 2A, so that their plasmonic nature (at THz and IR wavelengths) allows the engineering of hyperbolic modes.

Carriers (electrons) travelling through graphene can reach speeds close to their theoretical maximum (i.e., the Fermi velocity ν_{F} or approximately 106 meters per second) and exhibit a linear energy-momentum dispersion. Through energy and momentum conservation, the momentum of the electromagnetic waves generated by drifting electrons, which may be termed the “electron/photon coupling space,” can be calculated.

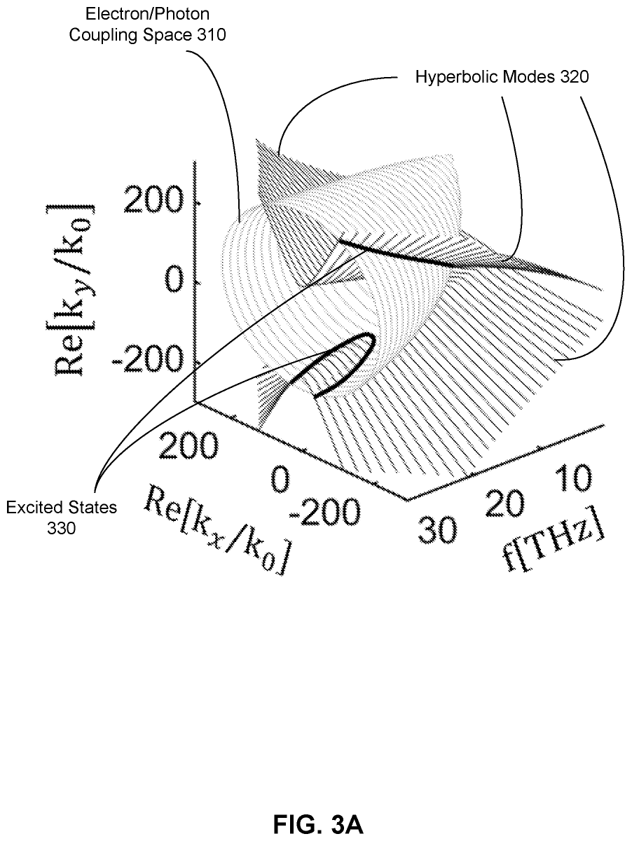

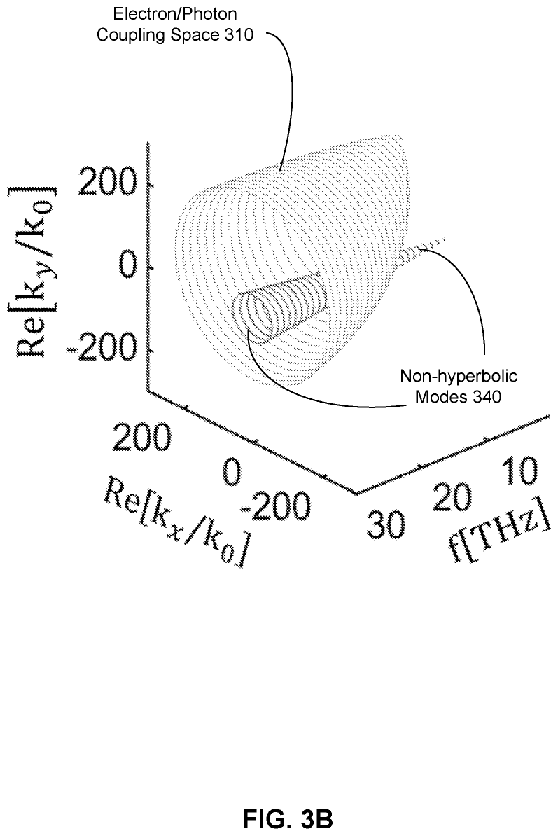

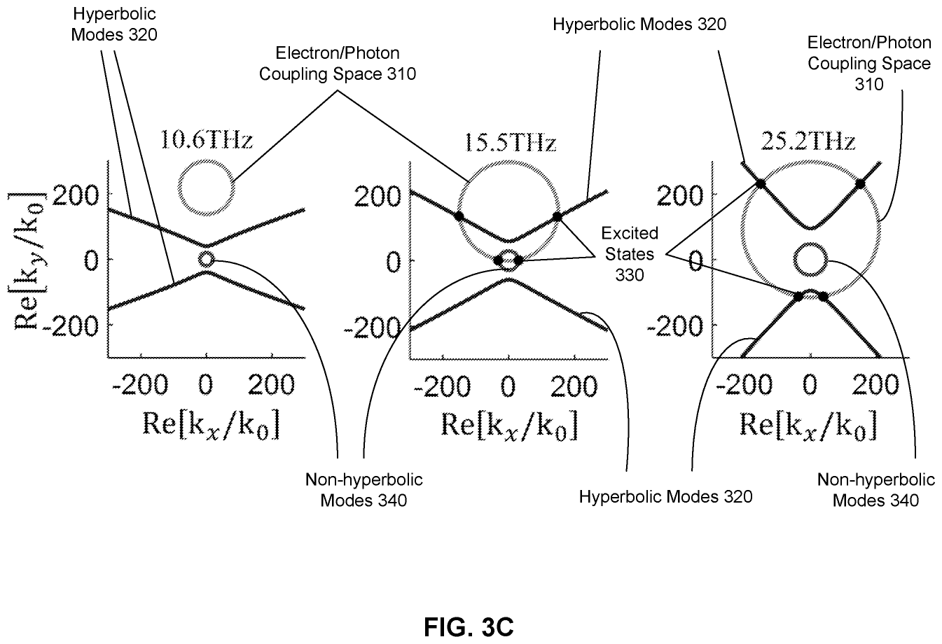

FIGS. 3A-C depict an electron/photon coupling space according to some embodiments. In these embodiments, coupling space 310 denotes the momentum of waves that can be generated by drifting electrons in graphene, and is cylindrical or conic in this representation. Hyperbolic modes 320 denote the momentum of states supported by a hyperbolic graphene nanostructure presented above, and may take the shape of substantially symmetrical troughs (one of them inverted) that bisect coupling space 310. The intersections between coupling space 310 and hyperbolic modes 320 identify excited states 330 associated with the generation of THz and/or IR waves.

It may be noted that, in contrast to the depiction in FIG. 3A, drifting electrons in non-hyperbolic systems are unable to efficiently excite common photonic modes. This is shown in FIG. 3B, which depicts the same electron/photon coupling space 310, along with non-hyperbolic modes 340 that denote the momentum of states supported by a non-hyperbolic graphene nanostructure. Significantly less overlap occurs between the coupling space and the non-hyperbolic modes, as shown more clearly in FIG. 3C.

FIG. 3C provides an alternative view of electron/photon coupling space 310, hyperbolic modes 320, and non-hyperbolic modes 340 that more clearly depicts excited states 330 (the black dots marking intersections between the coupling space and the modes) for both hyperbolic and non-hyperbolic modes for three different frequencies—10.6 THz, 15.5 THz, and 25.2 THz. Only at 15.5 THz do the non-hyperbolic modes 340 encounter excited states, while hyperbolic modes 320 encounter excited states at both 15.5 and 25.2 THz.

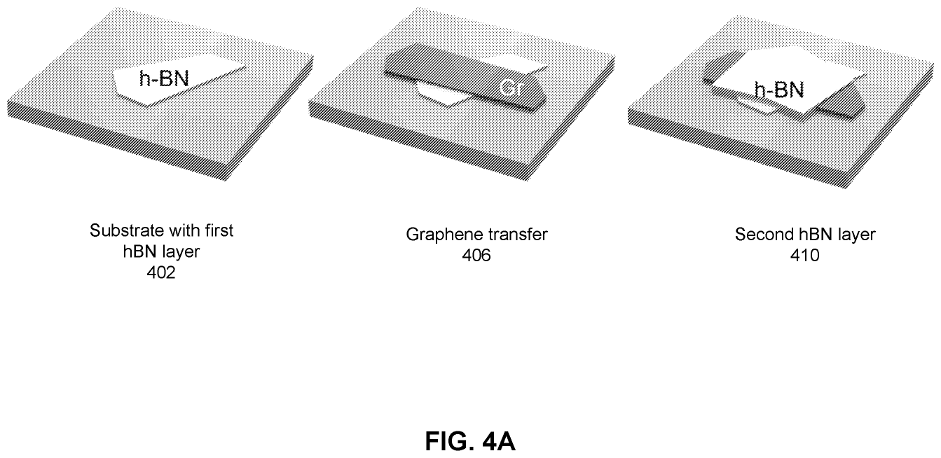

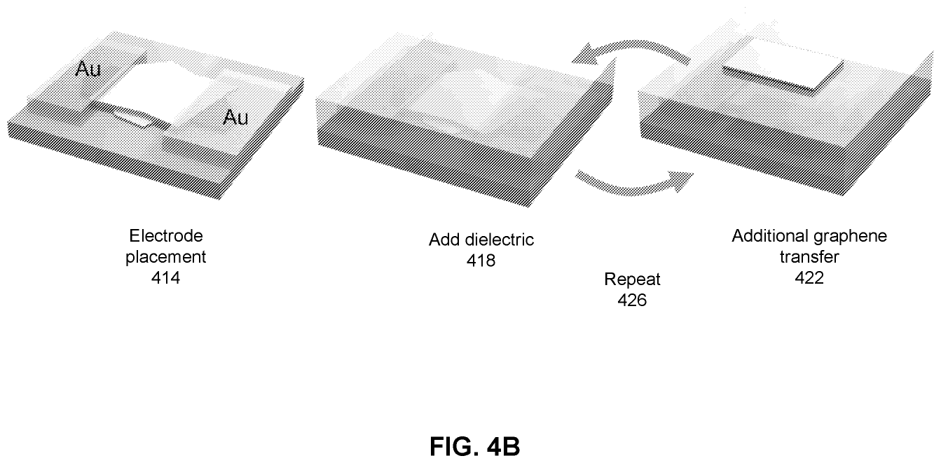

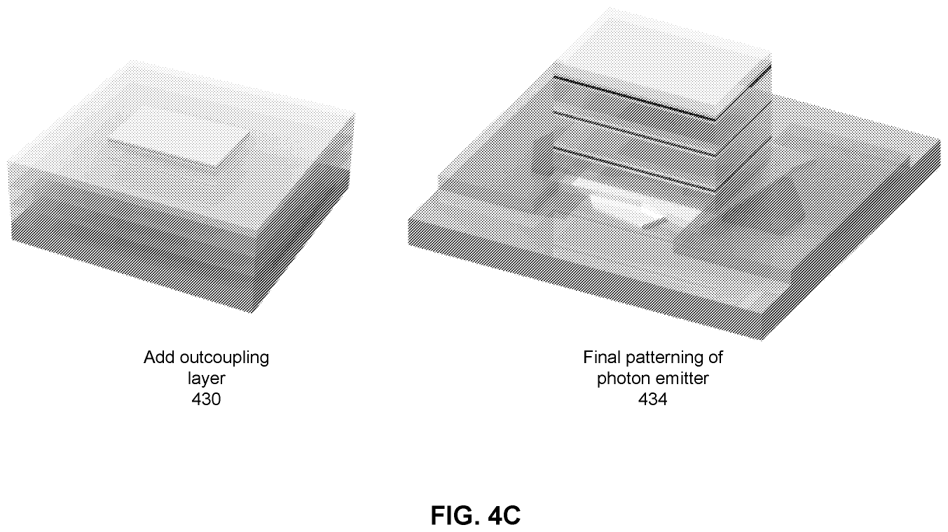

FIGS. 4A-C demonstrate construction of a stack hyperbolic metamaterial nanostructure for emitting CR in the form of photons, according to some embodiments. As shown in FIG. 4A, during a first step 402 a first layer of hexagonal boron nitride (hBN) is transferred, deposited or otherwise placed on a suitable substrate (e.g., a substrate suitable for a printed circuit board). In step 406 a first layer of graphene is deposited or placed upon the first layer of hBN. Step 410 completes a first hBN/graphene/hBN sandwich by placing a second hBN layer upon the nascent stack.

As illustrated in FIG. 4B, step 414 involves construction of electrodes from gold, silver, or some other efficient conductor. In step 418, a dielectric layer is added, which may involve immersing or encapsulating the existing stack structure (e.g., in SiO₂). Following the dielectric addition, another layer of graphene is placed in step 422, after which step 426 may be conducted any number of times to repeat steps 418 and 422. The number of iterations of step 426 may affect the performance characteristics of the nanostructure.

Then, as indicated in FIG. 4C, step 430 involves construction of the matching or outcoupling layer(s) atop the hyperbolic media. These layers may illustratively comprise one or more dielectric layers with tailored thickness and permittivity. Alternatively, they may comprise nanostructure surfaces, such as metallic gratings or subwavelength patches, or an array of nanoparticles that scatter the generated light into free-space. Lastly, in step 434, the structure is trimmed or shaped to yield the photon-emitting structure.

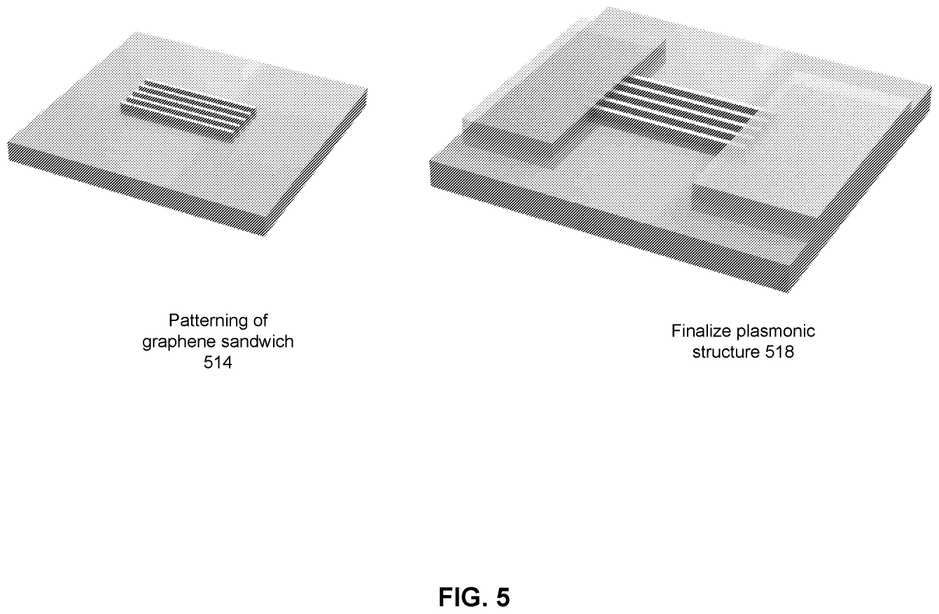

FIG. 5 demonstrates construction of a planar hyperbolic plasmonic nanostructure for emitting CR in the form of SPPs, according to some embodiments. In these embodiments, initial steps are identical to steps 402, 406, and 410 of FIG. 4A. Afterward, in step 514 the hBN/graphene/hBN sandwich atop the substrate is shaped or patterned into N parallel strips or ribbons of predetermined (e.g., and equal) widths that are separated by identical gaps. For example, after depositing the sandwich, e-beam lithography may be applied to form and separate individual ribbons. Thus, the strips are virtually identical in geometry, and the periodicity of the strips may be adjusted to alter the output of the nanostructure. Note that a top layer of hBN may be omitted in some implementations. In step 518, the plasmonic structure is finalized, which may involve construction of electrodes from gold, silver, or some other efficient conductor.

Although bias voltages are described as typical DC signals herein, they need not be so configured in all implementations. Thus, instead of a constant DC voltage, a pulsed or square wave voltage signal may be applied. Advantageously, pulses (e.g., with amplitudes of approximately 5 volts and with a periodicity of approximately 1 kHz) sweep all potential states and increase the efficiency of the structure.

The configuration of a stack or planar metamaterial nanostructure may be selected based on, for example, a particular use or application for the structure. That configuration will be compatible with certain determinable photonic modes, and the bias voltage to be applied to operate the structure may be selected for its compatibility with those modes. When a small footprint is desired, a planar metamaterial structure may be preferred because it enables greater miniaturization than a stack structure.

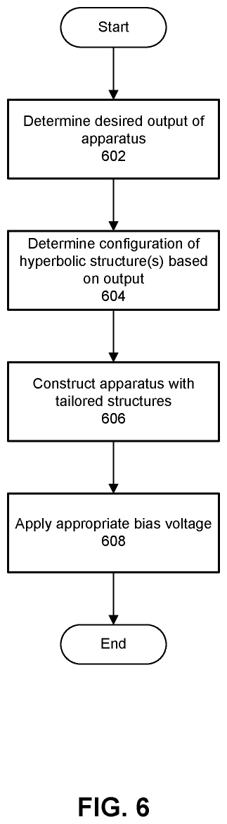

FIG. 6 is a flowchart demonstrating a method of emitting light in the form of Cherenkov radiation from an apparatus comprising one or more hyperbolic nanostructures, according to some embodiments.

In operation 602, a desired output of the apparatus is determined, which may be influenced by the function or application of the apparatus. For example, in some applications (e.g., some medical devices), a particular frequency range of the CR light output may be desired, in terms of lower and/or upper frequency of the output light spectrum, whether a more or less directional emission is desired (e.g., emission into free space, planar wave-based emission), etc.

In operation 604, configuration of the hyperbolic structure(s) of the apparatus is determined, based on the desired output. For example, configuration of one or more stack structures may be determined in terms of number of hyperbolic layers, widths of each layer, overall height of the stack, etc. Similarly, configurations of planar structures (e.g., ribbons) may be determined in terms of width, length, separations, etc.

In operation 606, the apparatus is constructed, possibly using a method described above. Finally, in operation 608, a suitable bias voltage is applied. As discussed previously, the strength and/or shape of the bias voltage may impact the output CR, in which case an optimal configuration may be determined through testing or experimentation.

Methods and processes described in the detailed description can be embodied as code and/or data, which may be stored in a non-transitory computer-readable storage medium as described above. When a processor or computer system reads and executes the code and manipulates the data stored on the medium, the processor or computer system performs the methods and processes embodied as code and data structures and stored within the medium.

Furthermore, the methods and processes may be programmed into hardware modules such as, but not limited to, application-specific integrated circuit (ASIC) chips, field-programmable gate arrays (FPGAs), and other programmable-logic devices now known or hereafter developed. When such a hardware module is activated, it performs the methods and processes included within the module.

The foregoing embodiments have been presented for purposes of illustration and description only. They are not intended to be exhaustive or to limit this disclosure to the forms disclosed. Accordingly, many modifications and variations will be apparent to practitioners skilled in the art. The scope is defined by the appended claims, not the preceding disclosure.

What is claimed is:

1. An apparatus, comprising:
a substrate;
a bias voltage; and
one or more hyperbolic nanostructures comprising:
a substantially two-dimensional (2D) material for conveying electrons provided by the bias voltage; and
one or more layers of plasmonic and/or dielectric materials;
wherein the electrons flow on the 2D material and couple to hyperbolic modes and/or surface plasmon polaritons (SPPs) engineered by the plasmonic and/or dielectric materials; and
wherein the apparatus emits light in the form of Cherenkov radiation (CR) during application of the bias voltage.

2. The apparatus of claim 1, wherein the 2D material comprises at least one of:
graphene;
transition metal dichalcogenides (TMDs);
black phosphorous;
a set of carbon nanotubes; and
an electron gas.

3. The apparatus of claim 2, wherein:
the 2D material comprises graphene; and
the apparatus further comprises at least one of:
one or more low-loss matching layers;
gratings and/or nanopatterns on one or more surfaces of the hyperbolic nanostructures; and
nanoparticles and/or quantum dots on one or more surfaces of the hyperbolic nanostructures.

4. The apparatus of claim 1, wherein the 2D material comprises graphene encapsulated in hexagonal boron nitride (hBN).

5. The apparatus of claim 1, wherein the 2D material comprises one or more layers of graphene nanopatterned with specific shapes to create hyperbolic modes.

6. The apparatus of claim 5, wherein the apparatus emits the Cherenkov radiation in the form of electromagnetic plane waves.

7. The apparatus of claim 1, wherein the plasmonic material comprises at least one layer of nanostructures that support surface plasmon polaritons (SPPs).

8. The apparatus of claim 7, wherein the apparatus emits the Cherenkov radiation in the form of SPPs.

9. The apparatus of claim 1, wherein the apparatus emits electromagnetic radiation within a Terahertz range, an infrared range, and/or a visible range.

10. The apparatus of claim 1, wherein the apparatus is portable.

11. The apparatus of claim 1, further comprising:
electrodes coupled to the hyperbolic nanostructures for conveying the bias voltage.

12. An apparatus, comprising:
a substrate;
contacts for introducing a bias voltage to the apparatus; and
multiple hyperbolic strips through which electrons drift in response to the bias voltage;
wherein Cherenkov radiation in the form of surface plasmon polaritons is emitted when the electrons couple with photonic modes of the hyperbolic strips.

13. The apparatus of claim 12, wherein each hyperbolic strip comprises a strip of graphene.

14. The apparatus of claim 13, wherein each hyperbolic strip further comprises at least one strip of hexagonal boron nitride.

15. The apparatus of claim 12, wherein the Cherenkov radiation is emitted within a Terahertz frequency range or an infrared frequency range.

16. An apparatus, comprising:
a substrate;
contacts for introducing a bias voltage to the apparatus;
multiple hyperbolic layers through which electrons drift in response to the bias voltage; and
one or more matching layers that emit Cherenkov radiation in the form of photons when the electrons couple with photonic modes of the hyperbolic layers.

17. The apparatus of claim 16, further comprising:
a layer of dielectric between adjacent hyperbolic layers.

18. The apparatus of claim 16, wherein each hyperbolic layer comprises a layer of graphene.

19. The apparatus of claim 18, wherein each hyperbolic layer further comprises multiple layers of hexagonal boron nitride sandwiching the layer of graphene.

20. The apparatus of claim 16, wherein the Cherenkov radiation is emitted within a Terahertz frequency range or an infrared frequency range.

21. The apparatus of claim 16, wherein the apparatus is portable.

22. A method of generating Cherenkov radiation (CR), the method comprising:
fabricating one or more two-dimensional graphene-based hyperbolic media; and
applying a bias voltage to the hyperbolic media;
wherein electrons flowing through the hyperbolic media are coupled with broadband hyperbolic photonic modes to emit the CR.

23. The method of claim 22, wherein the one or more two-dimensional graphene-based hyperbolic media comprise a stack composed of multiple layers of the graphene-based hyperbolic interleaved with dielectrics.

24. The method of claim 23, wherein the CR comprises photons in the form of electromagnetic plane waves in free-space.

25. The method of claim 22, wherein the one or more two-dimensional graphene-based hyperbolic media comprise at least one nanopatterned layer of graphene deposited upon hexagonal boron nitride (hBN).

26. The method of claim 25, wherein the CR comprises surface plasmon polaritons (SPPs) in the Terahertz, infrared and/or visible ranges.

27. A method of generating Cherenkov radiation (CR), comprising:
fabricating one or more two-dimensional graphene-based hyperbolic media; and
applying a bias voltage to the hyperbolic media;
wherein electrons flowing through the hyperbolic media are coupled with broadband hyperbolic photonic modes to emit the CR.

28. The method of claim 27, wherein the one or more two-dimensional graphene-based hyperbolic media comprise a stack composed of multiple layers of the graphene-based hyperbolic interleaved with dielectrics.

29. The method of claim 28, wherein the CR comprises photons in the form of electromagnetic plane waves in free-space.

30. The method of claim 27, wherein the one or more two-dimensional graphene-based hyperbolic media comprise at least one nanopatterned layer of graphene deposited upon hexagonal boron nitride (hBN).

31. The method of claim 30, wherein the CR comprises surface plasmon polaritons (SPPs) in the TeraHertz, infrared and/or visible ranges.

32. The method of claim 27, further comprising:
using the CR to perform wireless communication.

33. The method of claim 27, further comprising:
using the CR to perform imaging.

34. The method of claim 27, further comprising:
adjusting the bias voltage to modify a lower frequency and intensity of emission of the CR radiation.

35. The method of claim 27, wherein:
electrons flowing through the two-dimensional graphene-based hyperbolic media are phase-matched with broadband hyperbolic modes of the two-dimensional graphene-based hyperbolic media.
